(19) United States
(12) Patent Application Publication
(10) Pub. No.: US 2024/0164115 A1
(43) Pub. Date: May 16, 2024

(54) SEMICONDUCTOR DEVICE AND ELECTRONIC APPARATUS INCLUDING THE SAME

(71) Applicant: Samsung Electronics Co., Ltd., Suwon-si (KR)

(72) Inventors: Jinseong HEO, Suwon-si (KR); Minsu SEOL, Suwon-si (KR); Yunseong LEE, Suwon-si (KR); Dongmin KIM, Suwon-si (KR); Sanghyun JO, Suwon-si (KR); Dukhyun CHOE, Suwon-si (KR)

(73) Assignee: Samsung Electronics Co., Ltd., Suwon-si (KR)

(21) Appl. No.: 18/504,760

(22) Filed: Nov. 8, 2023

(30) Foreign Application Priority Data
Nov. 11, 2022 (KR) 10-2022-0150977

(51) Int. Cl. H10B 53/30; H01L 21/28; H01L 29/04; H01L 29/51

(52) U.S. Cl. CPC H10B 53/30; H01L 29/045; H01L 29/40111; H01L 29/516

(57) ABSTRACT

Provided are a semiconductor device including a ferroelectric and an electronic apparatus including the semiconductor device. The semiconductor device includes a semiconductor layer, an electrode apart from the semiconductor layer, and a ferroelectric layer arranged between the semiconductor layer and the electrode. The ferroelectric layer includes a plurality of crystal grains, each of which having a first crystal orientation aligned within an angle range with respect to a first direction and having a second crystal orientation aligned within an angle range with respect to a second direction that is different from the first direction.

### CROSS-REFERENCE TO RELATED APPLICATIONS

This application is based on and claims priority under 35 U.S.C. § 119 to Korean Patent Application No. 10-2022-0150977, filed on Nov. 11, 2022, in the Korean Intellectual Property Office, the disclosure of which is incorporated by reference herein in its entirety.

### BACKGROUND

Various example embodiments relate to a semiconductor device and/or an electronic apparatus including the same, and more particularly, to a semiconductor device including crystal grains having a controlled crystal orientation, and/or to an electronic apparatus including the semiconductor device.

Ferroelectrics are materials with ferroelectricity, which may indicate that internal electric dipole moments are aligned to maintain a spontaneous polarization without an external electric field applied thereto. Ferroelectrics are materials in which a polarization (or an electric field) remains semi-permanently even after a specific (e.g. nonzero) voltage is applied thereto and the voltage is returned to 0 V. Research for applying such ferroelectric characteristics to a logic device or a memory device has continued.

### SUMMARY

Provided are a semiconductor device including a ferroelectric layer with controlled crystal orientations, and/or an electronic apparatus including the semiconductor device.

Additional aspects will be set forth in part in the description which follows and, in part, will be apparent from the description, or may be learned by practice of various example embodiments.

According to various example embodiments, a semiconductor device includes a semiconductor layer, an electrode arranged apart from the semiconductor layer, and a ferroelectric layer arranged between the semiconductor layer and the electrode and including a plurality of crystal grains, each of which has a first crystal orientation aligned within a first angle range, e.g. a first preset angle range, with respect to a first direction and a second crystal orientation aligned within a second angle range, e.g. a preset second angle range, with respect to a second direction that is different from the first direction.

The first direction and the second direction may be perpendicular to each other.

The first direction may be parallel to a direction from the semiconductor layer to the electrode.

The second direction may be any one of directions parallel to a surface of the semiconductor layer.

The first angle range of the first direction may be within about 30 degrees with respect to the first direction.

The first crystal orientation may be any one of a [111] crystal orientation, a [112] crystal orientation, and a [211] crystal orientation of the plurality of crystal grains.

The second crystal orientation may be any one of a [010] crystal orientation and a [110] crystal orientation of the plurality of crystal grains.

The plurality of crystal grains may further have a third crystal orientation aligned within a third angle range of with respect to a third direction that is different from the first direction and the second direction.

A width of the ferroelectric layer may be less than or equal to about 10 nm.

A thickness of the ferroelectric layer may be less than or equal to about 10 nm.

The semiconductor device may further include a paraelectric layer between the semiconductor layer and the ferroelectric layer.

The paraelectric layer may include material in an amorphous phase.

The paraelectric layer may include an oxide of at least one selected from Hf, Si, Al, Zr, Y, La, Gd, and Sr.

The ferroelectric layer may contact, e.g. may directly contact the semiconductor layer.

A percentage of the plurality of crystal grains in the ferroelectric layer having the first and second orientations may be greater than or equal to about 20%.

The ferroelectric layer may include a material having an orthorhombic crystal structure of about 40% or more.

The ferroelectric layer may include an oxide of at least one of Si, Al, Hf, and Zr.

The ferroelectric layer may include the oxide as a base material, and may further include at least one of Si, Al, Y, La, Gd, Mg, Ca, Sr Ba, Ti, Zr, Hf, and N as a dopant material.

The semiconductor layer may include a first region and a second region each having dopants of a conductive material, the first and second regions arranged apart from each other.

The semiconductor device may further include a pillar extending in a first direction, in which the semiconductor layer surrounds a side of the pillar, the electrode includes a plurality of sub-electrodes arranged apart from each other in the first direction, and the ferroelectric layer includes a plurality of sub-ferroelectric layers arranged between each of the plurality of sub-electrodes and the semiconductor layer.

### BRIEF DESCRIPTION OF THE DRAWINGS

The above and other aspects, features, and advantages of various example embodiments of the disclosure will be more apparent from the following description taken in conjunction with the accompanying drawings, in which:

FIG. 1 is a cross-sectional view schematically showing a structure of a semiconductor device according to various example embodiments;

FIG. 2A illustrates a semiconductor device including crystal grains with random crystal orientations;

FIG. 2B illustrates a semiconductor device including crystal grains with a crystal orientation parallel to a stacking direction;

FIG. 2C illustrates a semiconductor device including crystal grains with a plurality of crystal orientations aligned in a particular direction, according to various example embodiments;

FIG. 3 shows a semiconductor device in which a ferroelectric layer is arranged on a semiconductor layer, according to various example embodiments;

FIG. 4A is a transmission electron microscope (TEM) cross-sectional image for HfZrO₄ that is a ferroelectric material formed on MoS₂ that is a two-dimensional (2D) material;

FIG. 4B shows a diffractive pattern of a cross-sectional image of FIG. 4A;

FIG. 4C is a planar image of a TEM for HfZrO₄ that is a ferroelectric material of FIG. 4A;

FIG. 5 is a cross-sectional view schematically showing a structure of a semiconductor device according to another embodiment;

FIG. 6 shows a capacitor including a ferroelectric layer according to various example embodiments;

FIG. 7 is a schematic block diagram of a display driver integrated circuit (DDI) and a display device including the DDI, according to various example embodiments.

FIG. 8 is a block diagram of an electronic apparatus according to various example embodiments.

FIG. 9 is a block diagram of an electronic apparatus according to various example embodiments;

FIG. 10 is a conceptual view schematically showing a device architecture applicable to an electronic apparatus according to various example embodiments; and

FIG. 11 is a conceptual view schematically showing a device architecture applicable to an electronic apparatus according to another embodiment.

### DETAILED DESCRIPTION

Reference will now be made in detail to various embodiments, examples of which are illustrated in the accompanying drawings, wherein like reference numerals refer to like elements throughout. In this regard, the present embodiments may have different forms and should not be construed as being limited to the descriptions set forth herein. Accordingly, example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, various example embodiments disclosed herein will be described in detail with reference to the accompanying drawings. In the drawings, like reference numerals denote like components, and sizes of components in the drawings may be exaggerated for convenience of explanation. Meanwhile, various embodiments to be described are merely examples, and various modifications may be made from such example embodiments.

When an expression “above” or “on” may include not only “directly on/under/at left/right contractually”, but also “on/under/at left/right contactlessly”. Singular forms include plural forms unless apparently indicated otherwise contextually. When a portion is referred to as “comprises” a component, the portion may not exclude another component but may further include another component unless stated otherwise.

The use of the terms of “the above-described” and similar indicative terms may correspond to both the singular forms and the plural forms. When there is an explicit description of the order of operations of the method or there is no description contrary thereto, these operations may be performed in an appropriate order and the order is not necessarily limited to the described order.

The term used herein such as “unit” or “module” indicates a unit for processing at least one function or operation, and may be implemented in hardware, software, or in a combination of hardware and software.

Connections of lines or connection members between components shown in the drawings are illustrative of functional connections and/or physical or circuit connections, and in practice, may be represented as alternative or additional various functional connections, physical connections, or circuit connections.

The use of all examples or other terms is only to describe technical spirit in detail, and the scope is not limited by these examples or terms unless limited by the claims.

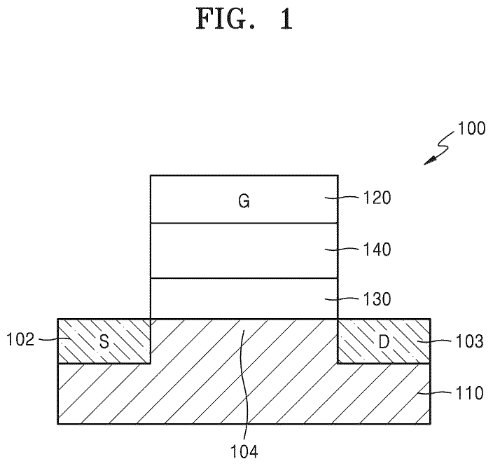

FIG. 1 is a cross-sectional view schematically showing a structure of a semiconductor device 100 according to various example embodiments. Referring to FIG. 1, the semiconductor device 100 according to various example embodiments may include a semiconductor layer 110 including a first source/drain region 102 and a second source/drain region 103 arranged apart from each other, and a channel region 104 arranged between the first source/drain region 102 and the second source/drain region 103.

The semiconductor layer 110 may include at least one semiconductor material among, for example, group IV semiconductors such as silicon (Si), germanium (Ge), SiGe, etc., group III-V compound semiconductors such as GaAs, GaP, etc., group II-VI compound semiconductors, oxide semiconductors, and two-dimensional material semiconductors.

The first source/drain region 102 and the second source/drain region 103 may be arranged on both sides of an upper surface of the semiconductor layer 110. A channel region 104 may be a partial region of the semiconductor layer 110.

The first source/drain region 102 and the second source/drain region 103 may be formed by doping/implanting one or both sides of an upper portion of the semiconductor layer 110 with the same or different dopants at the same or different concentrations. The first source/drain region 102 and the second source/drain region 103 may be doped as a first conductive type, and the channel region 104 may be doped as a second conductive type that is electrically opposite to the first conductive type. For example, the channel region 104 may include a p-type semiconductor and the first source/drain region 102 and the second source/drain region 103 may include an n-type semiconductor, or the channel region 104 may include an n-type semiconductor and the first source/drain region 102 and the second source/drain region 103 may include a p-type semiconductor.

When the semiconductor layer 110 includes Si, Ge, SiGe, etc., the first source/drain region 102 and the second source/drain region 103 may be doped with a dopant of at least one of Ph, As, and Sb and may be doped with the same or different dopants at the same or different energies, and the channel region 104 may be doped with a dopant of at least one of B, Al, Ga, and In; however, example embodiments are not limited thereto.

Although not shown in the drawing, the semiconductor device 100 may further include a source/drain electrode arranged on each of the first source/drain region 102 and the second source/drain region 103. Additional functional layers for reducing a contact resistance between a semiconductor and a metal or preventing or reducing the amount of and/or the likelihood of and/or the impact of diffusion of a metal may be further arranged between the first source/drain region 102 and the source/drain electrode and between the second source/drain region 103 and the source/drain electrode.

The semiconductor device 100 may further include a gate electrode 120 arranged apart from the semiconductor layer 110. The gate electrode 120 may include one or more selected from a group including a metal, a metal nitride, a metal carbide, polysilicon, and a combination thereof. For example, the metal may include one or more of aluminum (Al), tungsten (W), molybdenum (Mo), titanium (Ti), or tantalum (Ta), and the metal nitride may include a titanium nitride film (TiN film) or a tantalum nitride film (TaN film), and the metal carbide may include aluminum- or silicon-doped (or contained) metal carbide, and a specific example thereof may include one or more of TiAlC, TaAlC, TiSiC, or TaSiC.

The gate electrode 120 may have a structure in which a plurality of materials are stacked. For example, the gate electrode 120 may have a stacked structure of a metal nitride layer/metal layer such as TiN/AI, etc., or a stacked structure of a metal nitride layer/metal carbide layer/metal layer such as TiN/TiAlC/W. The gate electrode 120 may include a titanium nitride (TiN) film and/or molybdenum (Mo), and the foregoing examples may be used as variously modified forms. The gate electrode 120 may or may not also include a conductive two-dimensional material as well as the aforementioned material. For example, the conductive two-dimensional material may include at least one of graphene, black phosphorus, amorphous boron nitride, two-dimensional hexagonal boron nitride (h-BN), and phosphorene.

The semiconductor device 100 may further include a paraelectric layer 130 arranged between the semiconductor layer 110 and the gate electrode 120. The paraelectric layer 130 may be arranged on the channel region 104. The paraelectric layer 130 may have paraelectric characteristics. The paraelectric layer 130 may include at least one of, for example, a silicon oxide and a metal oxide having a high permittivity. The paraelectric layer 130 may include, for example, an oxide of at least one selected from Hf, Si, Al, Zr, Y, La, Gd, and Sr. However, example embodiments are not limited thereto.

The paraelectric layer 130 may be in an amorphous phase. As the paraelectric layer 130 is in an amorphous phase, an influence between a crystal structure of the ferroelectric layer 140 and a crystal structure of the channel region 104 may be reduced.

The paraelectric layer 130 may be deposited on a channel 115 of a substrate 110 using a deposition method such as, for example, one or more of chemical vapor deposition (CVD), atomic layer deposition (ALD), physical vapor deposition (PVD), etc.

The semiconductor device 100 may further include the ferroelectric layer 140 arranged between the paraelectric layer 130 and the gate electrode 120. The ferroelectric layer 140 may include a ferroelectric material. The ferroelectric material is a material with ferroelectricity in which internal electric dipole moments are aligned to maintain a spontaneous polarization without an external electric field applied thereto. A threshold voltage of the semiconductor device 100 may change with a polarization direction of the ferroelectric layer 140, e.g., a direction from the gate electrode 120 to the channel region 104 or, conversely, a direction from the channel region 104 to the gate electrode 120. In this sense, the semiconductor device 100 may be a ferroelectric field effect transistor (FeFET). The semiconductor device 100 may be applied to, for example, a non-volatile memory device and/or a logic device.

The ferroelectric layer 140 may include an oxide of at least one selected from, for example, Hf, Si, Al, Zr, Y, La, Gd, and Sr. However, this is merely an example. The ferroelectric layer 140 may further include a dopant depending on a need or a desire. Herein, the dopant may include at least one selected from, for example, Si, Al, Zr, Y, La, Gd, Sr, and Hf. When the ferroelectric layer 140 includes a dopant, the dopant may be doped at the same concentration as a whole or at different concentrations for different regions. Different doping materials may be doped for different regions of the ferroelectric layer 140. Thicknesses of the gate electrode 120, the paraelectric layer 130, and the ferroelectric layer 140 may be the same as each other, or at least one thickness of the gate electrode 120, the paraelectric layer 130, and the ferroelectric layer 140 may be greater than or less than a thickness of at least one other of the gate electrode 120, the paraelectric layer 130, and the ferroelectric layer 140.

The paraelectric layer 130 and the ferroelectric layer 140 may include the same material. The ferroelectric layer 140 may have ferroelectric characteristics, but the paraelectric layer 130 may not have the ferroelectric characteristics. For example, when the ferroelectric layer 140 and the paraelectric layer 130 include a hafnium oxide, a crystal structure of the hafnium oxide included in the ferroelectric layer 140 may be different from a crystal structure of the hafnium oxide included in the paraelectric layer 130.

The ferroelectric layer 140 may include a polycrystalline phase. The ferroelectric layer 140 may have various crystal structures such as, for example, a monoclinic system, a tetragonal system, an orthorhombic system, a cubic system, etc. The ferroelectric layer 140 may include an orthorhombic crystal structure of about 40% or more, about 50% or more, or about 60% or more.

The crystal grains included in the ferroelectric layer 140 may have a plurality of crystal orientations. For example, the crystal grains having the tetragonal crystal structure may have crystal orientations such as [001], [100], [hk0], [0k0], etc. (in which h and k are natural numbers that are greater than or equal to zero). The crystal grains having the orthorhombic crystal structure may have crystal orientations such as [111], [010], [110], [112], [211], etc. Indications such as [001], [100], [hk0], [0k0], [111], [010], [110], [112], [211], etc., express Miller indices indicating crystal orientations in a crystal structure.

The ferroelectric layer 140 according to various example embodiments may include crystal grains in a polycrystalline phase and having a plurality of crystal orientations aligned in a specific direction. A rate or percentage of crystal grains having a plurality of crystal orientations aligned in a specific direction in the ferroelectric layer 140 may be about 20% or more, about 30% or more, or about 50% or more.

For example, the ferroelectric layer 140 may include a plurality of crystal grains having a first crystal orientation aligned within a certain first range of a first direction and may have a second crystal orientation aligned within a certain second range (which may be greater than, less than, or equal to the first range) of a second direction that is different from the first direction. The certain range of the first direction may be within about 30 degrees with respect to the first direction, and the certain range of the second direction may be within about 30 degrees with respect to the second direction. The first direction may be oriented from the semiconductor layer 110 to the gate electrode 120, and the second direction may be perpendicular to the first direction. The second direction may be any one of directions parallel to the surface of the semiconductor layer 110. For example, the second direction may be oriented from the second source/drain region 103 to the first source/drain region 102. When the crystal grains have the tetragonal crystal structure, the first crystal orientation may be any one of a [100] crystal orientation, a [hk0] crystal orientation, and a [0k0] crystal orientation, and the second crystal orientation may be a [001] crystal orientation. When the crystal grains have the orthorhombic crystal structure, the first crystal orientation may be any one of a [111] crystal orientation, a [112] crystal orientation, and a [211] crystal orientation, and the second crystal orientation may be any one of a [010] crystal orientation and a [110] crystal orientation.

Alternatively or additionally, the ferroelectric layer 140 may include a plurality of crystal grains having the first crystal orientation aligned within the certain range of the first direction, the second crystal orientation aligned within the certain range of the second direction that is different from the first direction, and the third crystal orientation aligned within the certain range of the third direction that is different from the first and second directions. The certain range of the first direction may be within about 30 degrees with respect to the first direction, the certain range of the second direction may be within about 30 degrees with respect to the second direction, and the certain range of the third direction may be within about 30 degrees with respect to the third direction. The first direction may be oriented from the semiconductor layer 110 to the gate electrode 120, the second direction may be perpendicular to the first direction, and the third direction may be perpendicular to the first and second directions. Each of the second and third directions may be any one of directions parallel to the surface of the semiconductor layer 110. For example, the second direction may be oriented from the second source/drain region 103 to the first source/drain region 102, and the third direction may be perpendicular to a direction oriented from the second source/drain region 103 to the first source/drain region 102. When the crystal grains have the tetragonal crystal structure, the first crystal orientation is any one of [100] directions, the second crystal orientation may be a [001] direction, and the third crystal orientation may be a [0k0] direction.

Crystal grains in which each of the plurality of crystal orientations are aligned in a specific direction have high regularity, such that the dispersion of the crystal grains may be reduced. Thus, even when the size of the semiconductor device 100 decreases and/or the density of the semiconductor device 100 increases, fluctuation of a threshold voltage may be minimized or reduced.

Alternatively or additionally, as the crystal grains included in the ferroelectric layer 140 have a plurality of crystal orientations aligned in a specific direction, a remaining polarization may be increased, thus improving polarization characteristics of a thin film. Alternatively or additionally, polarization orientations are aligned, increasing a depolarization field and improving a negative capacitance effect, thereby further reducing a sub-threshold swing and thus further improving performance of an electronic device.

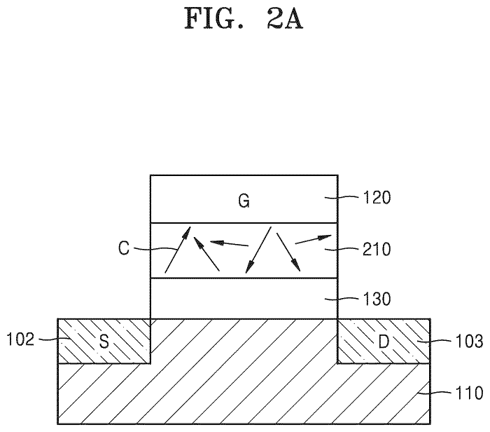

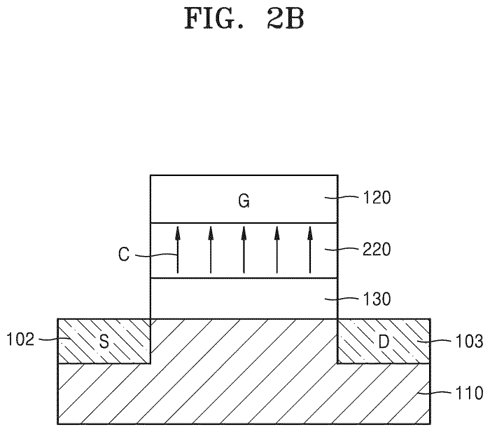

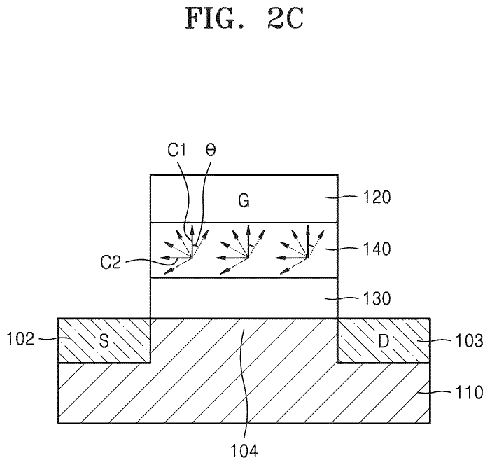

FIG. 2A illustrates a semiconductor device 200 including crystal grains with random (e.g. isotropic) crystal orientations. As a paraelectric layer 230 is in an amorphous phase, crystal grains included in a ferroelectric layer 240 may have a random crystal orientation C, e.g. an orientation uniformly random, when the ferroelectric layer 240 is grown on the paraelectric layer 130. As the crystal orientation C is random or uniformly random, the dispersion of the crystal grains increases, making it difficult to minimize or reduce a device and increase the density of the device.

Meanwhile, when the ferroelectric layer is deposited on the paraelectric layer through an atomic layer deposition process and a crystallization process is performed by heat treatment, the crystal orientation of the crystal grains may be aligned in an orientation which may reduce the surface energy of the ferroelectric layer. By performing heat treatment on a ferroelectric material layer having a large width and a small thickness, some crystal orientations of the crystal grains may be aligned in a direction to low surface energy, e.g., in a direction parallel to a deposition direction (e.g., a Z-axis direction).

FIG. 2B illustrates a semiconductor device 200a including crystal grains with a crystal orientation parallel to a stacking direction. When a thickness of the ferroelectric layer 240 is less than or equal to about 10 nm, some crystal orientations C of the crystal grains may be aligned in a direction to low surface energy, e.g., in a direction parallel to a deposition direction in a heat treatment process of the ferroelectric layer 240. However, other crystal orientations of the crystal grains may be still aligned at random on a surface perpendicular to the deposition direction.

The ferroelectric layer 140 according to various example embodiments may be formed by a selective atomic layer deposition (ALD) process. When the ferroelectric layer 140 is selectively formed on the paraelectric layer 130, the plurality of crystal orientations of the crystal grains may be aligned in a specific direction. As a ferroelectric material is selectively deposited, the direction to the low surface energy may be a surface other than a surface contacting the paraelectric layer 130. Thus, the crystal grains may be crystallized in direction to low surface energy in a process of being crystallized by heat treatment. Crystal orientations may be aligned with a direction parallel to the width direction of the ferroelectric layer 140 as well as a direction parallel to the thickness direction of the ferroelectric layer 140.

FIG. 2C illustrates the semiconductor device 100 including crystal grains with a plurality of crystal orientations aligned in various particular directions. The thickness of the ferroelectric layer 140 may be less than or equal to about 10 nm, and the width of the ferroelectric layer 140 may be less than or equal to about 10 nm. A ferroelectric material may be formed on the paraelectric layer 130 by a selective atomic layer deposition process, and crystal orientations C1 and C2 of the crystal grains may be aligned in a direction to low surface energy in a heat treatment process.

For example, the crystal grains included in the ferroelectric layer 140 may include the plurality of crystal grains having the first crystal orientation C1 aligned within the certain range 6 with respect to the first direction and the second crystal orientation C2 aligned within the certain range 6 with respect to the second direction that is different from the first direction. The certain angle range 6 of the first direction may be within about 30 degrees with respect to the first direction, and the certain range 6 of the second direction may be within about 30 degrees with respect to the second direction. The second direction may be perpendicular to the first direction or may have an angle less than 90 degrees with the first direction. The first direction may be oriented from the semiconductor layer 110 to the gate electrode 120, and the second direction may be any one of directions parallel to the surface of the semiconductor layer 110.

Although not shown in the drawing, the crystal grains included in the ferroelectric layer 140 may further include the third crystal orientation aligned within a certain range of a third direction that is different from the first and second directions. The certain range of the third direction may be within about 30 degrees with respect to the third direction. The third direction may be perpendicular to the first and second directions. For example, the third direction may be perpendicular to a direction from the second source/drain region 103 to the first source/drain region 102.

Formation of the crystal grains of the ferroelectric layer 140 may be performed by a selective atomic layer deposition process and a heat treatment process (e.g., a heat treatment process of about 300° C. to about 1500° C.). The selective atomic layer deposition process and the heat treatment process may be sequentially performed, and the selective atomic layer deposition process may be performed at high temperature. Alternatively, when one ferroelectric layer 140 is formed, the selective atomic layer deposition process and the heat treatment process may be performed repeatedly a plurality of times.

Alternatively or additionally, to form the ferroelectric layer 140 including the plurality of crystal gains having the plurality of crystal orientations aligned in a specific direction, a ferroelectric material layer having a thickness of about 10 nm or less may be deposited on the paraelectric layer 130 and then may be etched to have a width of about 10 nm or less. As the thickness and width of the ferroelectric material layer are small, by performing heat treatment on the ferroelectric material layer, the crystal orientations of the crystal grains may be aligned in a direction to low surface energy and the crystal grains may be crystallized.

While it is shown in FIG. 1 that the ferroelectric layer 140 is arranged on the amorphous paraelectric layer 130, example embodiments are not limited thereto. The ferroelectric layer 140 may be arranged in a layered pattern having a specific crystal structure.

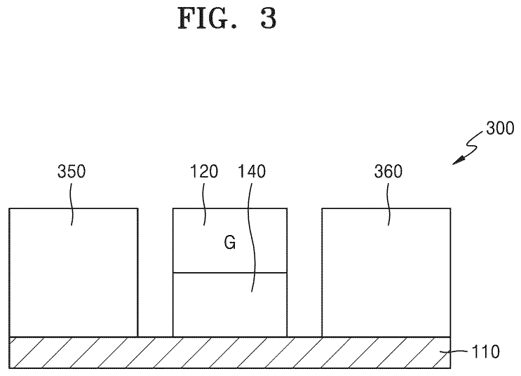

FIG. 3 shows a semiconductor device 300 in which a ferroelectric layer 340 is arranged on a semiconductor layer 310, according to various example embodiments. Referring to FIG. 3, the semiconductor device 300 may include a semiconductor layer 110, a source electrode 350 and a drain electrode 360 that are arranged apart from each other on the semiconductor layer 110, a gate electrode 120 arranged apart from the semiconductor layer 110, and a ferroelectric layer 140 arranged between the semiconductor layer 310 and the gate electrode 120.

The semiconductor layer 110 may be formed of or may include a two-dimensional (2D) material having a 2D crystal structure. The 2D material may have a layered structure of a monolayer or multilayer. Each layer of the 2D material may have a thickness in an atomic level. The 2D material may include at least one of, for example, graphene, black phosphorous, or transition metal dichalcogenide (TMD).

TMD may include, for example, a transition metal of one or more of Mo, W, Nb, V, Ta, Ti, Zr, Hf, Tc, and Re, and a chalcogen element of one of or more of S, Se, and Te. TMD may be expressed as, for example, MX₂, in which M indicates a transition metal and X indicates a chalcogen element. For example, M may be Mo, W, Nb, V, Ta, Ti, Zr, Hf, Tc, Re, etc., and X may be S, Se, Te, etc. Thus, for example, TMD may include MoS₂, MoSe₂, MoTe₂, WS₂, WSe₂, WTe₂, ZrS₂, ZrSe₂, HfS₂, HfSe₂, NbSe₂, ReSe₂, and so forth. Alternatively, TMD may not be expressed as MX₂. In this case, for example, TMD may include CuS that is a compound of a transition metal, Cu, and a chalcogen element, S. Meanwhile, TMD may be a chalcogenide material including a non-transition metal. The non-transition metal may include, for example, Ga, In, Sn, Ge, Pb, etc. In this case, TMD may include a compound of a non-transition metal such as Ga, In, Sn, Ge, Pb, etc., and a chalcogenide element such as S, Se, or Te. For example, TMD may include SnSe₂, GaS, GaSe, GaTe, GeSe, In₂Se₃, InSnS₂, etc.

As such, TMD may include a metal element selected from Mo, W, Nb, V, Ta, Ti, Zr, Hf, Tc, Re, Cu, Ga, In, Sn, Ge, and Pb, and a chalcogen element selected from S, Se, and Te. However, the aforementioned materials are examples, and other materials may be used as a TMD material.

The thickness of the semiconductor layer 110 may be as thin as about 3 nm or less. By applying the semiconductor layer 110 including the 2D material to the semiconductor device 300, scaling of the semiconductor device 300 may be reduced.

The ferroelectric layer 140 may be arranged adjacent to the semiconductor layer 110. When the semiconductor layer 110 includes a 2D material having a 2D crystal structure, the semiconductor layer 110 may have an inactive surface while having defects, in a boundary between the crystal structures of the semiconductor layer 1, for example, a grain boundary of the semiconductor layer 110. Thus, the ferroelectric layer 140 may be selectively deposited on the semiconductor layer 110. For example, even when the ferroelectric layer 140 is formed by a general atomic layer deposition process instead of a selective deposition process, the ferroelectric material may be selectively deposited in the grain boundary of the semiconductor layer 110. Through heat treatment, the ferroelectric material may be crystallized with crystal orientations aligned in a plurality of directions in which surface energy is lowered.

The crystal grains included in the ferroelectric layer 140 may include the plurality of crystal grains having the first crystal orientation aligned within the certain range of the first direction and the second crystal orientation aligned within the certain range of the second direction that is different from the first direction. The certain range or certain angle range of the first direction may be within about 30 degrees with respect to the first direction, and the certain range of the second direction may be within about 30 degrees with respect to the second direction. The first direction may be oriented from the semiconductor layer 110 to the gate electrode 120, and the second direction may be perpendicular to the first direction. The second direction may be any one of directions parallel to the surface of the semiconductor layer 110. The crystal grains included in the ferroelectric layer 340 may further include the third crystal orientation aligned within a certain range of the third direction that is different from the first direction and the second direction. The certain range of the third direction may be within about 30 degrees with respect to the third direction. The third direction may be perpendicular to the first and second directions. The material and the characteristics of the ferroelectric layer have been described above, and thus will not be described in detail.

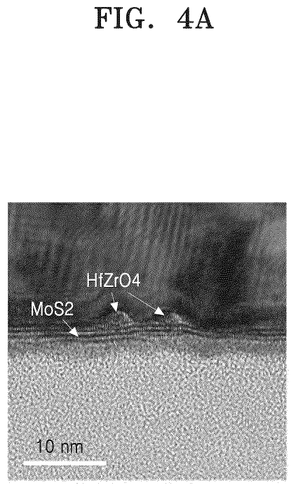

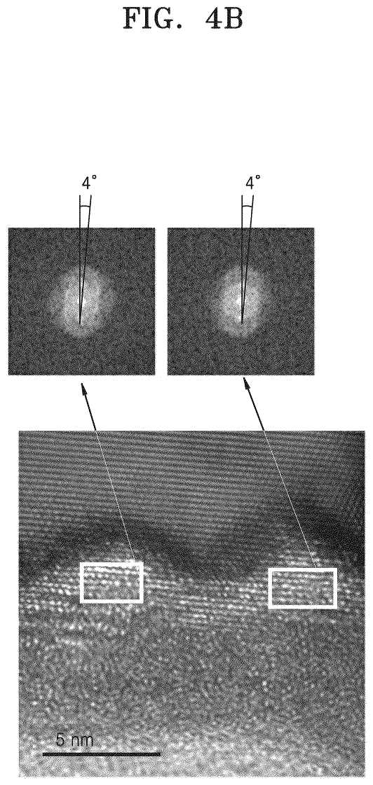

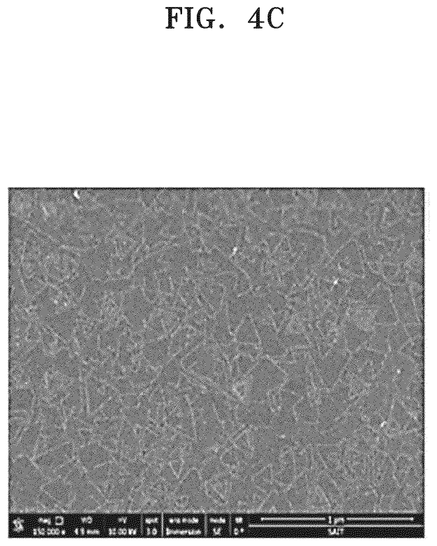

An experiment has been conducted to check whether the polycrystal ferroelectric layer 140 is formed on the semiconductor layer 110 having a 2D crystal structure. FIG. 4A is a TEM cross-sectional image for HfZrO₄ that is a ferroelectric material formed on MoS₂ that is a 2D material, FIG. 4B shows a diffractive pattern of a cross-sectional image of FIG. 4A, and FIG. 4C is a planar image of a TEM for HfZrO₄ that is a ferroelectric material of FIG. 4A.

Referring to FIG. 4A, it may be seen that HfZrO₄ that is a ferroelectric material is selectively deposited on MoS₂ that is a 2D material. Referring to FIG. 4B, it may be seen that crystal grains located at different positions of a ferroelectric material have the same crystal structure. Referring to FIG. 4C, HfZrO₄ is a ferroelectric material that is in a polycrystal phase having various crystal structures. For example, it may be seen that the ferroelectric layer 340 has regularity that is similar to single crystal even when the ferroelectric layer 340 has the polycrystal phase.

The above-described semiconductor devices 100 and 300 may be applied to various electronic apparatuses. For example, the above-described semiconductor devices 100 and 300 may be used as a logic transistor and/or a memory transistor. The above-described semiconductor devices 100 and 300 may be used as memory cells, in which a plurality of memory cells are arranged two-dimensionally, are arranged in a vertical or horizontal direction, or are arranged in a direction to form a memory cell string, and a plurality of memory cell strings are arranged two-dimensionally to form a memory cell array. The above-described semiconductor devices 100 and 300 may form a part of an electronic circuit constituting an electronic apparatus, together with other circuit elements such as a capacitor, etc.

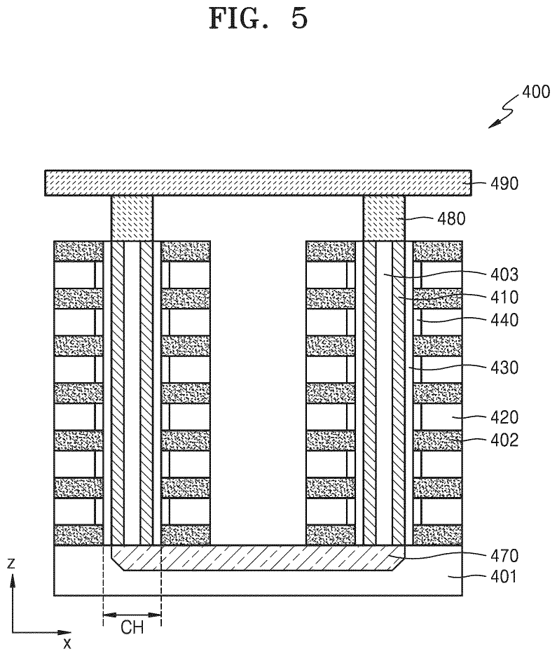

FIG. 5 is a cross-sectional view schematically showing a structure of a semiconductor device 400 according to another embodiment. The semiconductor device 400 shown in FIG. 5 may be or may include a memory cell string of a three-dimensional (3D) (or vertical) NAND (i.e., VNAND) or 3D FeFET memory.

Referring to FIG. 5, a substrate 401 may be provided. The substrate 401 may include a silicon material doped with a first-type impurity. For example, the substrate 401 may include a silicon material doped with a p-type impurity. Hereinbelow, the substrate 401 is assumed to include p-type silicon. However, the substrate 401 may not be limited to p-type silicon.

A plurality of gate electrodes 420 and a plurality of insulating devices 402 may be arranged alternately on the substrate 401. The plurality of gate electrodes 420 and the plurality of insulating devices 402 may be sequentially deposited while being alternated in the thickness direction of the substrate 401. The gate electrode 420 may include, for example, a metal material (e.g., one or more of copper, silver, etc.), and the plurality of insulating devices 402 may include, but not limited to, a silicon oxide. Each gate electrode 420 may be connected to one of a word line (not shown) and a string selection line (not shown).

A channel hole CH may be provided to vertically penetrate the plurality of gate electrodes 420 and the plurality of insulating devices 402 arranged alternately.

The channel hole CH may include a plurality of layers. In various example embodiments, an outermost layer of the channel hole CH may include the paraelectric layer 430. The paraelectric layer 430 may be conformally deposited in the channel hole CH. The material and the characteristics of the paraelectric layer 430 have been described above, and thus will not be described in detail.

Moreover, the semiconductor layer 410 may be conformally deposited along an inner side surface of the paraelectric layer 430. In various example embodiments, the semiconductor layer 410 may include a silicon material. Alternatively, the aforementioned semiconductor material such as Ge, IGZO, GaAs, etc., may be applied to the semiconductor layer 410. The semiconductor layer 410 may not be doped with a dopant. The semiconductor layer 401 may include a silicon material doped as a first type. The semiconductor layer 410 may include a silicon material doped as the same type as the substrate 401, and for example, when the substrate 401 includes a silicon material doped as a p type, the semiconductor layer 410 may also include a silicon material doped as the p type.

In the semiconductor layer 410, a pillar 403 may be arranged. For example, the pillar 403 may include a silicon oxide. For example, the pillar 403 may extend in a direction perpendicular to the surface of the substrate 401, and the semiconductor layer 410 may surround a side surface of the pillar 403.

A plurality of ferroelectric layers 440 may be arranged between the paraelectric layer 430 and the plurality of gate electrodes 420. Each of the thickness and width of the ferroelectric layer 440 may be less than or equal to about 10 nm. The material and the characteristics of the ferroelectric layer 440 have been described above, and thus will not be described in detail. When the semiconductor layer 410 is formed of a 2D material having a 2D crystal structure, the semiconductor device 400 of FIG. 5 may not include the paraelectric layer 130. For example, the ferroelectric layer 440 may directly contact the semiconductor layer 410.

A common source region 470 may be provided on the substrate 401. For example, the common source region 470 may have a second type that is different from the substrate 401. For example, the common source region 470 may be of an n type. Hereinbelow, the common source region 470 may be assumed to be of the n type. However, the common source region 470 may not be limited to the n type.

An end of the semiconductor layer 410 may contact the common source region 470, and the other end of the semiconductor layer 410 may contact a drain 480. The drain 480 may include a silicon material doped as a second type. For example, the drain 480 may include a silicon material doped as an n type.

A bit line 490 may be provided on the drain 480. The drain 480 and the bit line 490 may be connected through a contact plug. The bit line 490 may include a metal material, and for example, the bit line 490 may include polysilicon, and may or may not be doped with impurities. A conductive material may include a bit line.

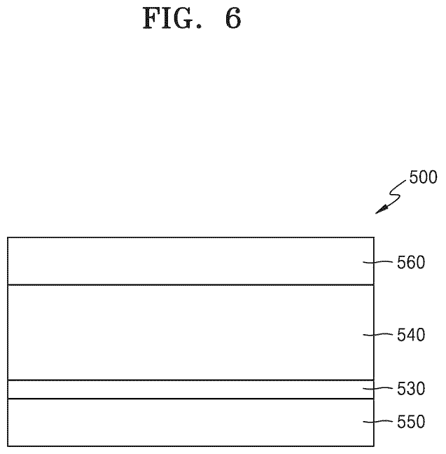

The ferroelectric layer 140 having the plurality of crystal orientations aligned in a specific direction may also be applied to the paraelectric layer 130 of a capacitor 500. FIG. 6 shows the capacitor 500 including the ferroelectric layer 140 according to various example embodiments.

Referring to FIG. 6, the capacitor 500 may include a lower electrode 550, an upper electrode 560 arranged apart from the lower electrode 550, and a paraelectric layer 530 and a ferroelectric layer 540 provided between the lower electrode 550 and the upper electrode 560.

The upper electrode 560 may be arranged apart from the lower electrode 550 to oppose the lower electrode 550. Each of the lower electrode 550 and the upper electrode 560 may include a metal, a conductive metal nitride, a conductive metal oxide, or a combination thereof.

The paraelectric layer 530 and the ferroelectric layer 540 may have the same material and characteristics as those of the paraelectric layer 530 and the ferroelectric layer 540 described above. When the lower electrode 550 is formed of a material having a 2D crystal structure, the capacitor 500 may not include the paraelectric layer 530.

The semiconductor devices 100, 300, 400, and 500 and/or an electronic device including the ferroelectric layer 540 according to various example embodiments may be applied to various electronic apparatuses, e.g., a display apparatus, a memory apparatus, etc.

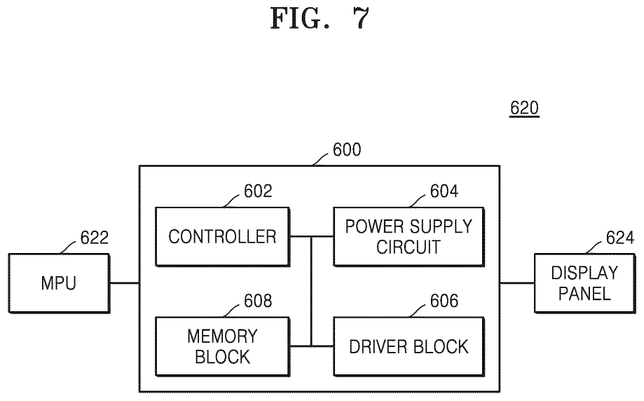

FIG. 7 is a schematic block diagram of a display driver integrated circuit (DDI) 600 and a display device 620 including the DDI 600, according to various example embodiments. Referring to FIG. 7, the DDI 600 may include a controller 602, a power supply circuit 604, a driver block 606, and a memory block 608. The controller 602 may receive and decode a command applied from a main processing unit (MPU) 622, and control each block of the DDI 600 to implement an operation corresponding to the command. The power supply circuit 604 may generate a driving voltage in response to control of the controller 602. The driver block 606 may drive a display panel 624 by using the driving voltage generated in the power supply circuit 604 in response to control of the controller 602. The display panel 624 may be or may include, for example, one or more of a liquid crystal display panel, an organic light-emitting device (OLED) display panel, or a plasma display panel. The memory block 608 may temporarily store a command input to the controller 602 or control signals output from the controller 602 or store required data, and may include memory, such as one or more of random access memory (RAM), read only memory (ROM), etc. For example, the memory block 608 may include the semiconductor devices 100 according various example embodiments.

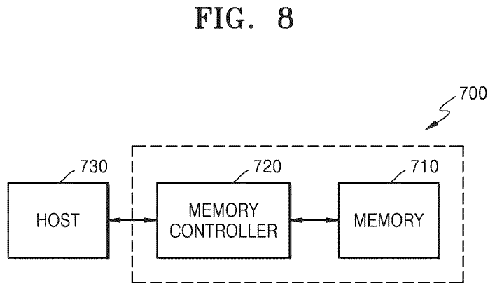

FIG. 8 is a block diagram of an electronic apparatus 700 according to various example embodiments. Referring to FIG. 8, the electronic apparatus 700 may include a memory 710 and a memory controller 720. The memory controller 720 may control the memory 710 for data reading from the memory 710 and/or data writing to the memory 710, in response to a request of a host 730. The memory 710 may include a semiconductor device according to the above-described embodiments.

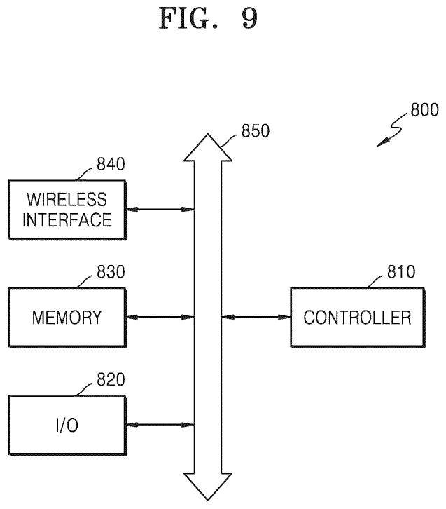

FIG. 9 is a block diagram of an electronic apparatus 800 according to various example embodiments. Referring to FIG. 9, the electronic apparatus 800 may constitute a wireless communication device and/or a device capable of transmitting and/or receiving information in a wireless environment. The electronic apparatus 800 may include a controller 810, an input/output device 1/O 820, a memory 830, and a wireless interface 840, which are connected to one another through a bus 850.

The controller 810 may include at least one of a microprocessor, a digital signal processor, or a processing device similar thereto. The input/output device 820 may include at least one of a keypad, a keyboard, or a display. The memory 830 may be used to store a command executed by the controller 810. For example, the memory 830 may be used to store user data. The electronic apparatus 800 may use the wireless interface 840 to transmit/receive data through a wireless communication network. The wireless interface 840 may include an antenna and/or a wireless transceiver. In some embodiments, the electronic apparatus 800 may be used in a communication interface protocol of a third-generation communication system, such as one or more of code division multiple access (CDMA), global system for mobile communications (GSM), North American digital cellular (NADC), extended-time division multiple access (E-TDMA), and/or wide band code division multiple access (WCDMA), etc. The memory 830 of the electronic apparatus 800 may include a semiconductor device according to the above-described embodiments.

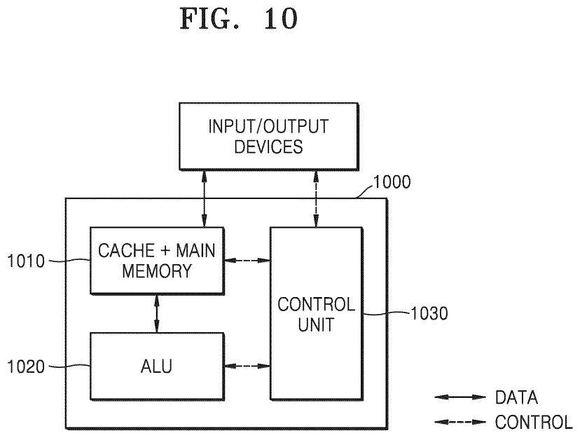

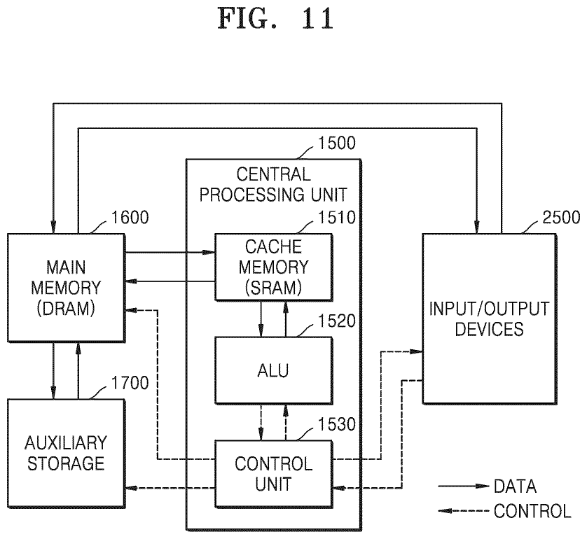

FIGS. 10 and 11 are conceptual views schematically showing a device architecture applicable to an electronic apparatus according to various example embodiments.

Referring to FIG. 10, an electronic device architecture 1000 may include a memory unit 1010 and a control unit 1030, and may further include an arithmetic logic unit (ALU) 1020. The memory unit 1010, the ALU 1020, and the control unit 1030 may be electrically connected to one another, e.g. connected in a wireless and/or wired manner. For example, the electronic device architecture 1000 may be implemented as one chip including the memory unit 1010, the ALU 1020, and the control unit 1030. More specifically, the memory unit 1010, the ALU 1020, and the control unit 1030 may communicate directly by being connected to one another through a metal line on-chip. The memory unit 1010, the ALU 1020, and the control unit 1030 may be monolithically integrated on one substrate to form one chip. An input/output device 2000 may be connected to the electronic device architecture (chip) 1000. The memory unit 1010 may include both a main memory and a cache memory. The electronic device architecture (chip) 1000 may be an on-chip memory processing unit. Each of the memory unit 1010, the ALU 1020, and/or the control unit 1030 may independently include the semiconductor device 100 according to the above-described embodiments.

Referring to FIG. 11, a cache memory 1510, an ALU 1520, and a control unit 1530 may constitute a central processing unit (CPU) 1500, and the cache memory 1510 may include a static random access memory (SRAM). A main memory 1600 and an auxiliary storage 1700 may be included in addition to the CPU 1500, and an input/output device 2500 may also be included. The main memory 1600 may be or may include, for example, a dynamic random access memory (DRAM), and may include the semiconductor device 100 according to the above-described embodiments.

Depending on a circumstance, the electronic device architecture may be implemented in a form where computing-unit devices and memory-unit devices are adjacent to each other in one chip, without distinction of sub-units.

While the semiconductor device and the electronic apparatus including the same described above have been described with reference to the embodiments described in the drawings, it will be understood by those of ordinary skill in the art that various modifications and equivalent other embodiments are possible therefrom. Therefore, the disclosed embodiments should be considered in a descriptive sense rather than a restrictive sense. The scope of the present specification is not described above, but in the claims, and all the differences in a range equivalent thereto should be interpreted as being included. Furthermore example embodiments are not necessarily mutually exclusive with one another. For example some example embodiments may include one or more features described with reference to one or more figures, and may also include one or more other features described with reference to one or more other figures.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

According to various example embodiments, crystal grains included in a ferroelectric layer have a plurality of crystal orientations aligned in a specific direction, thereby reducing a dispersion of the crystal grains. By reducing the dispersion of the crystal grains, the change of the characteristics of the threshold voltage may be reduced.

As the crystal grains included in the ferroelectric layer have the plurality of crystal orientations aligned in a specific direction, a remaining polarization may be increased, thus improving polarization characteristics of a thin film. Moreover, polarization orientations are aligned, increasing a depolarization field and improving a negative capacitance effect, thereby further reducing a sub-threshold swing and thus further improving performance of an electronic device.

It should be understood that embodiments described herein should be considered in a descriptive sense only and not for purposes of limitation. Descriptions of features or aspects within each example embodiment should typically be considered as available for other similar features or aspects in other example embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a semiconductor layer;
an electrode arranged apart from the semiconductor layer; and
a ferroelectric layer arranged between the semiconductor layer and the electrode and comprising a plurality of crystal grains, each of which has a first crystal orientation aligned within a first angle range with respect to a first direction and a second crystal orientation aligned within a second angle range with respect to a second direction that is different from the first direction.

2. The semiconductor device of claim 1, wherein the first direction and the second direction are perpendicular to each other.

3. The semiconductor device of claim 1, wherein the first direction is parallel to a direction from the semiconductor layer to the electrode.

4. The semiconductor device of claim 1, wherein the second direction is any one of directions parallel to a surface of the semiconductor layer.

5. The semiconductor device of claim 1, wherein the first angle range of the first direction is within about 30 degrees with respect to the first direction.

6. The semiconductor device of claim 1, wherein the first crystal orientation is any one of a [111] crystal orientation, a [112] crystal orientation, and a [211] crystal orientation of the plurality of crystal grains.

7. The semiconductor device of claim 1, wherein the second crystal orientation is any one of a [010] crystal orientation and a [110] crystal orientation of the plurality of crystal grains.

8. The semiconductor device of claim 1, wherein the plurality of crystal grains further have a third crystal orientation aligned within a third angle range with respect to a third direction that is different from the first direction and the second direction.

9. The semiconductor device of claim 1, wherein a width of the ferroelectric layer is less than or equal to about 10 nm.

10. The semiconductor device of claim 1, wherein a thickness of the ferroelectric layer is less than or equal to about 10 nm.

11. The semiconductor device of claim 1, further comprising:
a paraelectric layer between the semiconductor layer and the ferroelectric layer.

12. The semiconductor device of claim 11, wherein the paraelectric layer comprises a material having an amorphous phase.

13. The semiconductor device of claim 11, wherein the paraelectric layer comprises an oxide of at least one of Hf, Si, Al, Zr, Y, La, Gd, and Sr.

14. The semiconductor device of claim 1, wherein the ferroelectric layer directly contacts the semiconductor layer.

15. The semiconductor device of claim 1, wherein a percentage of the plurality of crystal grains in the ferroelectric layer having the first and second crystal orientation is equal to or greater than about 20%.

16. The semiconductor device of claim 1, wherein the ferroelectric layer comprises a material having an orthorhombic crystal structure of about 40% or more.

17. The semiconductor device of claim 1, wherein the ferroelectric layer comprises an oxide of at least one of Si, Al, Hf, and Zr.

18. The semiconductor device of claim 17, wherein the ferroelectric layer comprises the oxide as a base material, and further comprises at least one of Si, Al, Y, La, Gd, Mg, Ca, Sr Ba, Ti, Zr, Hf, or N as a dopant material.

19. The semiconductor device of claim 1, wherein the semiconductor layer comprises a first region and a second region each including dopants of a conductive material and arranged apart from each other.

20. The semiconductor device of claim 1, further comprising:
a pillar extending in a first direction,
wherein the semiconductor layer surrounds a side of the pillar,
the electrode comprises a plurality of sub-electrodes arranged apart from each other in the first direction, and
the ferroelectric layer comprises a plurality of sub-ferroelectric layers arranged between each of the plurality of sub-electrodes and the semiconductor layer.
